(19) United States
(12) Patent Application Publication
(10) Pub. No.: US 2018/0261653 A1
(43) Pub. Date: Sep. 13, 2018

(54) ORGANIC LIGHT EMITTING TOUCH DISPLAY SCREEN AND FABRICATING METHOD FOR THE SAME

(71) Applicant: Wuhan China Star Optoelectronics Technology Co., Ltd., Wuhan, Hubtel (CN)

(72) Inventor: Jian YE, Shenzhen, Guangdong (CN)

(73) Assignee: Wuhan China Star Optoelectronics Technology Co., L td., Wuhan, Hubei (CN)

(21) Appl. No.: 15/539,682

(22) PCT Filed: Mar. 29, 2017
(86) PCT No.: PCT/CN2017/078630

§ 371 Date: Jun. 25, 2017

(30) Foreign Application Priority Data
Feb. 27, 2017 (CN) 201710109872.5

(51) Int. Cl. H01L 27/32; G06F 3/041; H01L 51/52; H01L 51/56; G09G 3/3208

(52) U.S. Cl. CPC H01L 27/323; G06F 3/0412; G06F 3/0416; G06F 2203/04103; H01L 51/56; H01L 51/5253; G09G 3/3208; H01L 51/5221

(57) ABSTRACT

An organic light emitting touch display screen comprises an OLED display layer and a driving module. OLED display layer is layer-stacked with a cathode layer connected to the driving module. Cathode layer comprises inductive electrodes and touch control driving electrodes which are insulated and separated. In a display stage of the screen, the driving module applies display driving voltage on the cathode layer to accomplish a display function of the screen with cathode layer. In a touch stage of the screen, the driving module applies touch control voltage on said cathode layer to accomplish a touch control function of the inductive electrodes and the touch control driving electrodes. A fabricating method for an organic light emitting touch display screen is further provided.

### CROSS-REFERENCE TO RELATED APPLICATIONS

This application claims the benefit of the priority of Chinese Patent Application No. 2017101098725, entitled “organic light emitting touch display screen and fabricating method for the same”, filed on Feb. 27, 2017, disclosure of which is incorporated herein by reference.

### FIELD OF THE INVENTION

The present invention relates to a field of a touch display screen technology, and more particular to an organic light emitting touch display screen and a fabricating method for the same.

### BACKGROUND OF THE INVENTION

In conventional technology, a typical approach needs making touch control screen by alone for an Organic Light-Emitting Diode (OLED) display screen of a flexible touch control display screen, and then bonding an optical transparent adhesive on OLED to constitute a complete touch control display screen. This approach obviously increases an entire thickness of the touch control display screen.

### SUMMARY OF THE INVENTION

The present invention provides an organic light emitting touch display screen that decreases the entire thickness thereof, and a fabricating method.

The organic light emitting touch display screen introduced by the present invention, comprises an OLED display layer and a driving module, a surface of said OLED display layer is layer-stacked thereon with a cathode layer connected to the driving module, said cathode layer comprises inductive electrodes and touch control driving electrodes, said inductive electrodes and touch control driving electrodes are insulated and spaced apart from each other in dispositions thereof. In a display stage of the organic light emitting touch display screen, said driving module applies display driving voltage on the cathode layer so as to accomplish a display function of the organic light emitting touch display screen with said cathode layer, and in a touch stage of the organic light emitting touch display screen, said driving module applies touch control voltage on said cathode layer, so as to accomplish a touch control function of the inductive electrodes and the touch control driving electrodes.

Among them, said OLED display layer comprises a display region and a non-display region, two of said touch control driving electrodes located on said display region and separated by said inductive electrode are connected with each other in the non-display region through jumper.

Among them, two of said touch control driving electrodes are located on said non-display region and connected to each other through a metal bridge or through jumper.

Among them, said OLED display layer is layer-stacked thereon with a protective layer covering said cathode layer.

Among them, said touch control driving electrodes comprises a plurality of sub-electrodes arranged in multi-rows; said inductive electrodes comprises a plurality of sub-electrodes arranged in multi-columns, and each two of adjacent sub-electrodes of the touch control driving electrodes are separated by said inductive electrode.

Among them, said inductive electrodes and the touch control driving electrodes are embedded within said cathode layer or derived from said cathode layer itself.

A fabricating method for an organic light emitting touch display screen that the present invention provides, comprises:

forming a cathode layer having touch control driving electrodes and inductive electrodes, on a surface of an OLED display layer; and

forming a protective layer on said cathode layer.

Among them, forming the cathode layer having the touch control driving electrodes and the inductive electrodes on the surface of the OLED display layer comprises: forming the cathode layer on the surface of the OLED display layer, and patterning said cathode layer to form the touch control driving electrodes and the inductive electrodes.

Among them, patterning said cathode layer to form the touch control driving electrodes and the inductive electrodes applies a dry etching or a mask process.

Among them, the cathode layer having the touch control driving electrodes and the inductive electrodes is formed on the surface of the OLED display layer by way of vacuum deposition method.

Among them, said OLED display layer comprises a display region and a non-display region, two of said touch control driving electrodes located on said display region and separated by said inductive electrode are connected with each other in the non-display region through jumper; among them, two of said touch control driving electrodes are located on said non-display region and connected to each other through a metal bridge or through jumper.

Among them, said OLED display layer is layer-stacked thereon with a protective layer covering above said cathode layer.

Among them, said touch control driving electrodes comprises a plurality of sub-electrodes arranged in multi-rows; said inductive electrodes comprises a plurality of sub-electrodes arranged in multi-columns, and each two of adjacent sub-electrodes of the touch control driving electrodes are separated by said inductive electrode.

Among them, said inductive electrodes and the touch control driving electrodes are embedded within said cathode layer or derived from said cathode layer itself.

The organic light emitting touch display screen of the present invention integrates the inductive electrodes and the touch control driving electrodes onto the cathode layer treated as display driving, so as to construct a touch-control function screen, and decrease an entire thickness and a bonding process of the flexible touch control display screen.

### BRIEF DESCRIPTION OF THE DRAWINGS

To clearly set forth the structural characteristics and the beneficial effects of the present invention, the following description is detailed with accompanying figures and embodiments.

FIG. 1 depicts a cross-sectional schematic diagram of a organic light emitting touch display screen of the present invention;

FIG. 2 depicts a top-view diagram of the organic light emitting touch display screen shown in FIG. 1; and

FIG. 3 depicts a flow chart of a fabricating method for an organic light emitting touch display screen of the present invention.

### DETAILED DESCRIPTION OF PREFERRED EMBODIMENTS

The followings will incorporate the inventive embodiments with its drawings, for more clearly and completely describing the technical solution of the inventive embodiments, wherein the drawings are regarded as just an exemplar expression, which just represents schematic diagrams but can not be realized as limited to the present invention.

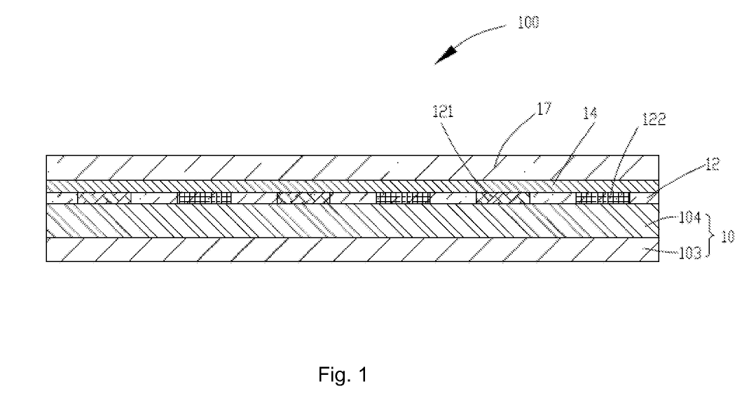

Referring to FIG. 1, an embodiment of the present invention provides a organic light emitting touch display screen 100, which comprises an OLED display layer 10 and a driving module 20, a surface of said OLED display layer is sequentially layer-stacked thereon with a cathode layer 12 connected with the driving module. Said cathode layer 12 comprises inductive electrodes 121 and touch control driving electrodes 122. Said inductive electrodes 121 and the touch control driving electrodes 122 are insulated and spaced apart from each other in dispositions thereof. Said inductive electrodes 121 and the touch control driving electrodes 122 are coupled with each other to form a mutual capacitance structure. In a display stage of the organic light emitting touch display screen, said driving module applies display driving voltage on the cathode layer 12 so as to accomplish a display function of the organic light emitting touch display screen 100 with said cathode layer 12, and in a touch stage of the organic light emitting touch display screen 100, said driving module applies touch control voltage on said cathode layer 12, so as to accomplish a touch control function of the inductive electrodes 121 and the touch control driving electrodes 122.

While displaying, said organic light emitting touch display screen 100 has timeliness and interval time that is too short to observe through eyes, so that during the user watches a change to touch control, the driving module timely alters the switches for the touch control function and display function, according to the status of the organic light emitting touch display screen 100 and operating signal.

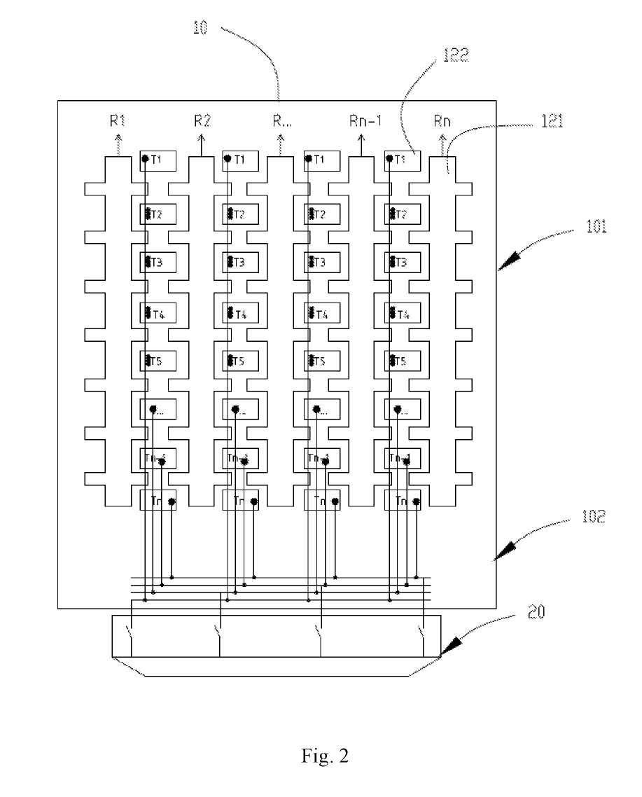

Referring to FIG. 2, in this embodiment, said touch control driving electrodes 122 comprises a plurality of sub-electrodes arranged in multi-rows; in this embodiment, substantially, are arranged in horizontal direction, and said inductive electrodes are spaced apart from each other along the horizontal direction; said inductive electrodes 121 comprises a plurality of sub-electrodes arranged in multi-columns; substantially, are arranged in vertical direction, and each two of adjacent sub-electrodes of the touch control driving electrodes 122 separated by said inductive electrodes 121. Said OLED display layer 10 comprises a display region 101 and a non-display region 102, two of said touch control driving electrodes 122, which are located on said display region 101 and separated said inductive electrodes 121, are connected with each other, through jumper 123, in the non-display region 102. Two of said touch control driving electrodes 122 are located on said non-display region 102 and connected to each other through a metal bridge or through jumper. In this embodiment, two of said touch control driving electrodes 122 in the non-display region 102 are connected with each other by employing the metal bridge therebetween.

Said OLED display layer 10 comprises an array substrate 103 and an OLED layer 104 disposed on said array substrate. Said OLED display layer 10 is layer-stacked thereon with a protective layer 14 covering above said cathode layer 12. The protective layer 14 is applicable for protecting said OLED display layer 10 from pollution of external moisture, oxygen and so forth. Said protective layer 14 is sequentially layer-stacked thereon with a polarizer (not shown) and a transparent cover plate 17.

Furthermore, said inductive electrodes 121 and the touch control driving electrodes 122 are embedded within said cathode layer 12 or derived from said cathode layer itself 12. In this embodiment, said inductive electrodes 121 and the touch control driving electrodes 122 are patterns which are formed by machining said cathode layer 1. Substantial method is referred to a fabricating method for an organic light emitting touch display screen, which the present invention provides. In other embodied approach, said cathode layer 12 is embedded therein by way of forming a plurality of insulating grooves, on the cathode layer, in accordance with deployments of the inductive electrodes 121 and the touch control driving electrodes 122, and injecting metal into grooves, so as to form said inductive electrodes 121 and the touch control driving electrodes 122.

In the present invention, the organic light emitting touch display screen 100 integrate the inductive electrodes 121 and the touch control driving electrodes 122 onto the cathode layer 12 treated as display driving, to construct a touch-control function screen. And, compared with the conventional technology that extraly makes a touch control screen to be bonded on the OLED display layer 1, this decreases an entire thickness and a bonding process of the organic light emitting touch display screen 100; thereby satisfying the demand on a slim screen body of flexible touch control display as well as simplifying process and effectively lowering fabricating cost.

Meanwhile, compared with the conventional technology where a single-layer conductive electrodes accomplishing the mutual capacitance commonly need to manufacture metal bridges for connecting two adjacent spaced-apart sub electrons, bridging implementation in the effective display region facilely causes drawbacks of worsening visibility, lowered display opening ratio and so forth. In the present invention, two of said touch control driving electrodes 122 located at said display region 101 and separated by said inductive electrodes 121 are connected to each other in the non-display region 102 through jumper 123. Two of said touch control driving electrodes 122 located at said non-display region 102 are connected to each other through a metal bridge or through jumper, so as to avoid the drawbacks of visibility/process complication, lowered display opening ratio and so fort, resulted from the requirement of implementing bridge structures in display region.

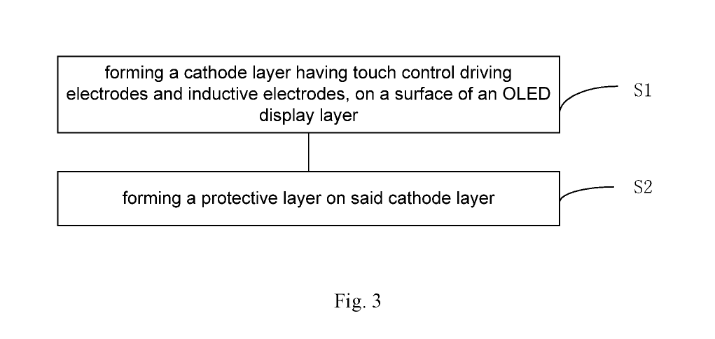

Referring to FIG. 3, a fabricating method for an organic light emitting touch display screen, which the present invention provides, comprises:

step S1, forming a cathode layer having touch control driving electrodes and inductive electrodes, on a surface of an OLED display layer; and

step S2, forming a protective layer on said cathode layer.

Among them, an implementing approach in the step S1 is that, forming the cathode layer having the touch control driving electrodes and the inductive electrodes on the surface of the OLED display layer comprises: forming the cathode layer on the surface of the OLED display layer, and patterning said cathode layer to form the touch control driving electrodes and the inductive electrodes.

Furthermore, patterning said cathode layer to form the touch control driving electrodes and the inductive electrodes applies a dry etching or a mask process.

Another implementing approach step S1 is that the cathode layer having the touch control driving electrodes and the inductive electrodes is formed on the surface of the OLED display layer by way of vacuum deposition method.

In the fabricating method for the organic light emitting touch display screen of the present invention, it is not required to extraly fabricate a touch control screen and then to bond the touch control screen on the OLED display layer, but directly integrates electrodes having touch control function onto the OLED display layer, thereby decreasing difficulty of machining process, and saving cost.

The aforementioned is as the preferred embodiments of the present invention, it should be to know that, to any persons who are ordinary skilled in the art, other related change or variances not departing from principle of the present invention can be made which should be covered by the protected scope of the subject claims of the present invention.

What is claimed is:

1. An organic light emitting touch display screen, wherein said organic light emitting touch display screen comprises an OLED display layer and a driving module, a surface of said OLED display layer is layer-stacked thereon with a cathode layer connected to the driving module, said cathode layer comprises inductive electrodes and touch control driving electrodes, said inductive electrodes and the touch control driving electrodes are insulated and spaced apart from each other in dispositions thereof, and in a display stage of the organic light emitting touch display screen, said driving module applies display driving voltage on the cathode layer to implement a display function of the organic light emitting touch display screen with said cathode layer, and in a touch stage of the organic light emitting touch display screen, said driving module applies touch control voltage on the cathode layer to implement a touch-control function of the inductive electrodes and the touch control driving electrodes.

2. The organic light emitting touch display screen as claimed in claim 1, wherein said OLED display layer comprises a display region and a non-display region, two of said touch control driving electrodes located on said display region and separated by said inductive electrode are connected with each other in the non-display region through jumper.

3. The organic light emitting touch display screen as claimed in claim 2, wherein two of said touch control driving electrodes are located on said non-display region and connected to each other through a metal bridge or through jumper.

4. The organic light emitting touch display screen as claimed in claim 1, wherein said OLED display layer is layer-stacked thereon with a protective layer covering said cathode layer.

5. The organic light emitting touch display screen as claimed in claim 3, wherein said touch control driving electrodes comprises a plurality of sub-electrodes arranged in multi-rows.

6. The organic light emitting touch display screen as claimed in claim 5, wherein said inductive electrodes comprises a plurality of sub-electrodes arranged in multi-columns, and each two of adjacent sub-electrodes of the touch control driving electrodes are separated by said inductive electrode.

7. The organic light emitting touch display screen as claimed in claim 1, wherein said inductive electrodes and the touch control driving electrodes are embedded within said cathode layer or derived from said cathode layer itself.

8. A fabricating method for an organic light emitting touch display screen, wherein said method comprises:
forming a cathode layer having touch control driving electrodes and inductive electrodes, on a surface of an OLED display layer; and
forming a protective layer on said cathode layer.

9. The fabricating method for the organic light emitting touch display screen as claimed in claim 8, wherein forming the cathode layer having the touch control driving electrodes and the inductive electrodes on the surface of the OLED display layer comprises: forming the cathode layer on the surface of the OLED display layer, and patterning said cathode layer to form the touch control driving electrodes and the inductive electrodes.

10. The fabricating method for the organic light emitting touch display screen as claimed in claim 9, wherein patterning said cathode layer to form the touch control driving electrodes and the inductive electrodes applies a dry etching or a mask process.

11. The fabricating method for the organic light emitting touch display screen as claimed in claim 8, wherein the cathode layer having the touch control driving electrodes and the inductive electrodes is formed on the surface of the OLED display layer by way of vacuum deposition method.

12. The fabricating method for the organic light emitting touch display screen as claimed in claim 8, wherein said OLED display layer comprises a display region and a non-display region, two of said touch control driving electrodes located on said display region and separated by said inductive electrode are connected with each other in the non-display region through jumper; wherein, two of said touch control driving electrodes are located on said non-display region and connected to each other through a metal bridge or through jumper.

13. The fabricating method for the organic light emitting touch display screen as claimed in claim 8, wherein said OLED display layer is layer-stacked thereon with a protective layer covering above said cathode layer.

14. The fabricating method for the organic light emitting touch display screen as claimed in claim 8, wherein said touch control driving electrodes comprises a plurality of sub-electrodes arranged in multi-rows; said inductive electrodes comprises a plurality of sub-electrodes arranged in multi-columns, and each two of adjacent sub-electrodes of the touch control driving electrodes are separated by said inductive electrode.

15. The fabricating method for the organic light emitting touch display screen as claimed in claim 8, wherein said inductive electrodes and the touch control driving electrodes are embedded within said cathode layer or derived from said cathode layer itself.
